(19) United States
(12) Patent Application Publication
(10) Pub. No.: US 2026/0047403 A1
(43) Pub. Date: Feb. 12, 2026

(54) METHOD FOR FABRICATING SEMICONDUCTOR DEVICE

(71) Applicant: SAMSUNG ELECTRONICS CO., LTD., SUWON-SI (KR)

(72) Inventors: Woo-Seok SHIM, Suwon-si (KR); Mingu KANG, Suwon-si (KR); Donggeon KIM, Suwon-si (KR); Taehoon PARK, Suwon-si (KR)

(21) Appl. No.: 19/200,960

(22) Filed: May 7, 2025

(30) Foreign Application Priority Data
Aug. 9, 2024 (KR) 10-2024-0106971
Mar. 13, 2025 (KR) 10-2025-0032931

(51) Int. Cl. H01L 21/027; G03F 7/00; G03F 7/20; H01L 23/544

(52) U.S. Cl. CPC H01L 21/0274; G03F 7/2022; G03F 7/70475; G03F 7/70633; H01L 23/544; H01L 2223/5446

(57) ABSTRACT

Provided is a method for fabricating a semiconductor device, the method including exposing a first pattern corresponding to a mask pattern to light in a first shot region of a substrate by using a photomask including the mask pattern, the first pattern extends in a first direction, and exposing a second pattern corresponding to the mask pattern to the light in a second shot region disposed adjacent to the first shot region of the substrate by using the photomask, the second pattern extends in a second direction, wherein the first direction crosses the second direction.

### CROSS-REFERENCE TO RELATED APPLICATION(S)

This application claims priority under 35 U.S. C. § 119 to Korean Patent Applications No. 10-2024-0106971, filed on Aug. 9, 2024, and No. 10-2025-0032931, filed on Mar. 13, 2025, in the Korean Intellectual Property Office, the entire contents of which are herein incorporated by reference.

### TECHNICAL FIELD

The present disclosure relates to a method for fabricating a semiconductor device.

### DISCUSSION OF THE RELATED ART

Generally, a photoresist pattern, used as an etching mask in a fabrication of a semiconductor device, is formed by performing an exposure process and a development process. A pattern having a desired shape is formed by etching an etching target film formed on a substrate by using the photoresist pattern as the etching mask.

As the semiconductor device becomes highly integrated, the pattern decreases in size. As a minute pattern is repeatedly formed, warpage occurs, which is a twist in the substrate of the semiconductor device in a predetermined direction.

### SUMMARY

According to an aspect, there is provided a method for fabricating a semiconductor device, the method including exposing a first pattern corresponding to a mask pattern to light in a first shot region of a substrate by using a photomask including the mask pattern, the first pattern extends in a first direction, and exposing a second pattern corresponding to the mask pattern to the light in a second shot region disposed adjacent to the first shot region of the substrate by using the photomask, the second pattern extends in a second direction, wherein the first direction crosses the second direction.

According to an aspect, there is provided a method for fabricating a semiconductor device, the method including exposing a first pattern corresponding to a mask pattern to light in a first shot region of a substrate by using a photomask including the mask pattern and exposing a second pattern corresponding to the mask pattern to the light in a second shot region adjacent to the first shot region of the substrate by using the photomask. The photomask includes a first edge configured to face another first edge, a second edge configured to face another second edge and cross the first edge, wherein a direction in which a first shot edge of the first shot region, which corresponds to the first edge, is extended and a direction in which a third shot edge of the second shot region, which corresponds to the first edge, is extended cross each other.

According to an aspect, there is provided a method for fabricating a semiconductor device, the method including exposing a first pattern corresponding to a mask pattern to light in a first shot region of a substrate by using a photomask including the mask pattern, the first pattern extends in a first direction, rotating the substrate by ninety degrees on a plane facing the photomask, and exposing a second pattern corresponding to the mask pattern to the light in a second shot region disposed adjacent to the first shot region of the substrate by using the photomask, the second pattern extends in a second direction, wherein the first direction crosses the second direction.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIGS. 1 and 2 are diagrams illustrating an intermediate operation for describing a method for fabricating a semiconductor device according to example embodiments of the present inventive concept;

FIG. 3 is a diagram for describing a photomask of FIGS. 1 and 2;

FIG. 4 is a diagram for describing a shot region of a substrate of a semiconductor device according to example embodiments of the present inventive concept;

FIG. 5 is an example diagram illustrating an enlargement of part P of FIG. 4;

FIG. 6 is an example diagram illustrating an enlargement of part Q of FIG. 5;

FIG. 7 is an example diagram illustrating an enlargement of part Q of FIG. 5 for describing a method for fabricating a semiconductor device according to example embodiments of the present inventive concept;

FIG. 8 is an example diagram illustrating an enlargement of part Q of FIG. 5 for describing a method for fabricating a semiconductor device according to example embodiments of the present inventive concept;

FIG. 9 is an example diagram illustrating an enlargement of part Q of FIG. 5 for describing a method for fabricating a semiconductor device according to example embodiments of the present inventive concept;

FIGS. 10, 11, 12, and 13 are diagrams for describing a method of fabricating a semiconductor device according to example embodiments of the present inventive concept;

FIG. 14 is a diagram for describing a photomask according to example embodiments of the present inventive concept;

FIGS. 15 and 16 are diagrams illustrating an intermediate operation for describing a method for fabricating a semiconductor device according to example embodiments of the present inventive concept;

FIG. 17 is a diagram for describing a shot region of a substrate of a semiconductor device according to example embodiments of the present inventive concept;

FIG. 18 is an example diagram illustrating an enlargement of part P of FIG. 17;

FIG. 19 is a flowchart for describing a method for forming a photo shot map of a semiconductor device according to example embodiments of the present inventive concept;

FIG. 20 is a diagram for describing operations S101 and S102 of FIG. 19;

FIG. 21 is a diagram for describing operations S103 and S104 of FIG. 19;

FIG. 22 is a flowchart for describing a method of forming a photo shot map of a semiconductor device according to example embodiments of the present inventive concept; and

FIG. 23 is a diagram for describing operations S201 and S202 of FIG. 22.

### DETAILED DESCRIPTION OF THE EMBODIMENTS

Before example embodiments are described, terms or words used in the present disclosure and the accompanying claims are not to be necessarily limited to general definitions or dictionary definitions. The terms and words are to be construed under a principle that an inventor may appropriately define a concept of a term in order to describe their invention in the best way. Thus, since example embodiments described in the present inventive concept and configurations illustrated in the accompanying drawings are merely most desirable example embodiments and do not represent all of the technical spirit of the present disclosure, it will be understood by those of ordinary skill in the art that various changes in form and details may be made thereto without departing from the spirit and scope of the present inventive concept.

Spatially relative terms, such as “beneath,” “below,” “lower,” “on,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly.

Hereinafter, the example embodiments of the present disclosure will be described with reference to the drawings.

An embodiment of the present inventive concept addresses the issues encountered when all shot regions of a substrate, where the light exposure is performed, are exposed to light in one direction.

In high-stack and high-integration semiconductor devices, in which components are stacked and integrated at high densities to achieve better performance and miniaturization, the semiconductor devices often include multiple layers of materials that are patterned with precision. As the shot regions of the substrate undergoes repeated exposure to light in a single direction, the substrate may experience stress in this specific direction. This may lead to saddle-type warpage, which manifests as twisting in the substrate.

By adjusting an alignment angle of the substrate relative to a photomask at a time of the exposure to the light for a first shot region and at a time of the exposure to the light for a second shot region, patterns in the shot regions may be disposed so as to cross and not to be extended in an identical direction.

By disposing of the patterns in the shot regions to have different alignment angles from each other, damage due to warpage of the substrate may decrease.

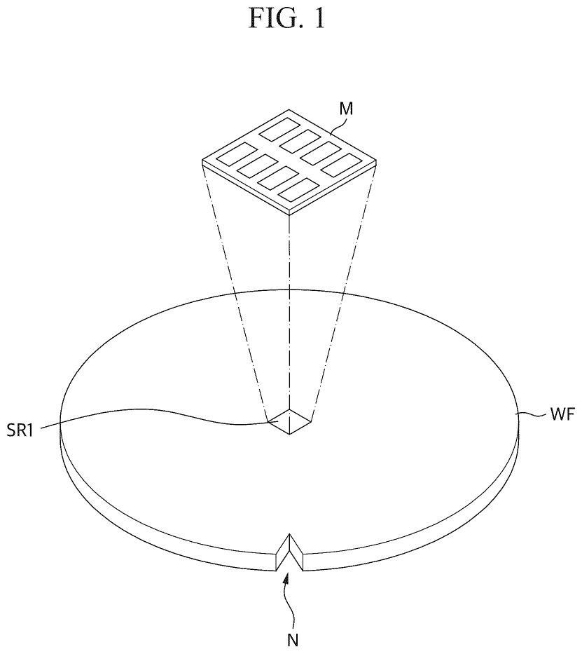

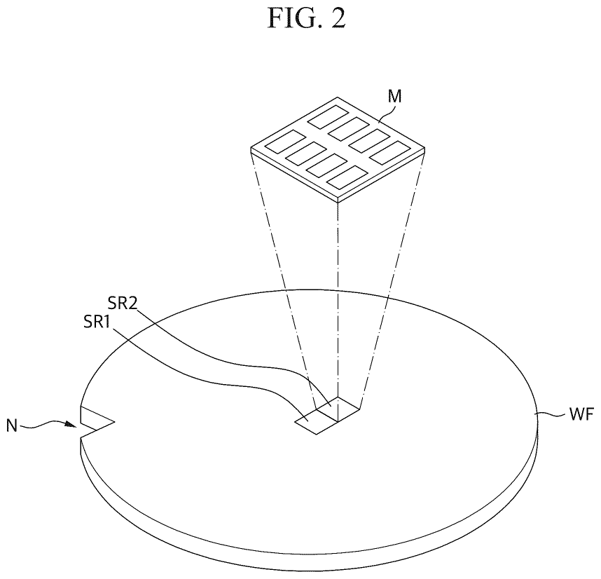

FIGS. 1 and 2 are diagrams illustrating an intermediate operation for describing a method for fabricating a semiconductor device according to example embodiments of the present inventive concept.

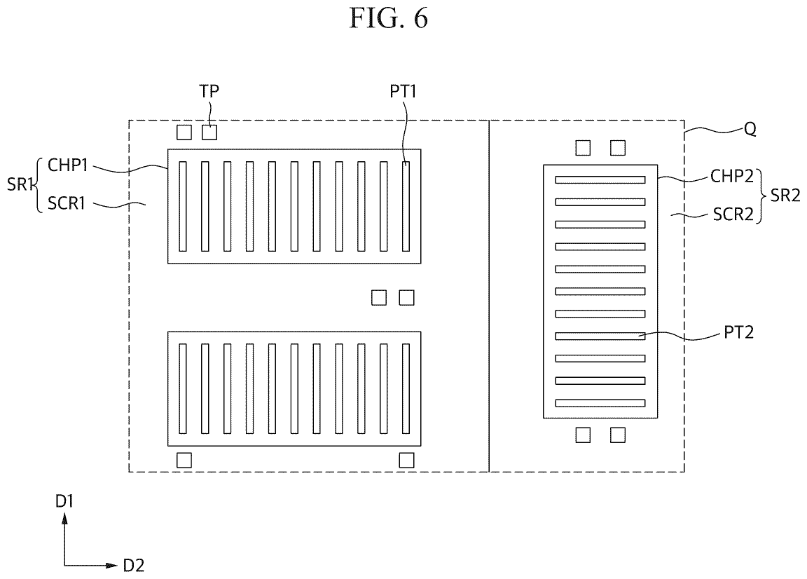

Referring to FIG. 1, the method for fabricating the semiconductor device according to example embodiments of the present inventive concept may include forming a pattern in a first shot region SR1 of a substrate WF by using a photomask M. The method for fabricating the semiconductor device according to example embodiments of the present inventive concept may include exposing a first pattern PT1 (of FIG. 6) to light in the first shot region SR1 by using the photomask M.

Then, referring to FIG. 2, the method for fabricating the semiconductor device according to example embodiments of the present inventive concept may include forming a pattern in a second shot region SR2 of the substrate WF by using the photomask M. The method for fabricating the semiconductor device according to example embodiments of the present inventive concept may include exposing a second pattern PT2 (of FIG. 6) to the light in the second shot region SR2 by using the photomask M. The second shot region SR2 may be disposed adjacent to the first shot region SR1. For example, one edge of the first shot region SR1 and one edge of the second shot region SR2 may be in contact with each other.

Referring back to FIGS. 1 and 2, the method for fabricating the semiconductor device may include rotating the substrate WF by ninety degrees. The substrate WF may be rotated by ninety degrees on a plane facing the photomask M. The substrate WF may be rotated by ninety degrees after pattern exposure to light for the first shot region SR1 and before pattern exposure to the light for the second shot region SR2. The substrate WF may be disposed on an identical plane at a time of the pattern exposure to the light for the first shot region SR1 and at a time of the pattern exposure to the light for the second shot region SR2.

According to example embodiments of the present inventive concept, alignment angles of the photomask M and the substrate WF in a case in which the first pattern PT1 (of FIG. 6) is exposed to the light in the first shot region SR1 and alignment angles of the photomask M and the substrate WF in a case in which the second pattern PT2 (of FIG. 6) is exposed to the light in the second shot region SR2 may differ. For example, in comparison with disposition of the substrate WF in the case in which the first pattern PT1 (of FIG. 6) is exposed to the light in the first shot region SR1, disposition of the substrate WF in the case in which the second pattern PT2 (of FIG. 6) is exposed to the light in the second shot region SR2 may be in a state of being rotated by ninety degrees. For example, a notch part N of the substrate WF at the time of the exposure to the light for the first shot region SR1 and the notch part N of the substrate WF at the time of the exposure to the light for the second shot region SR2 may be disposed at positions rotated by ninety degrees from each other on an identical plane.

According to example embodiment of the present inventive concept, the notch part N may be disposed at a circumference of the substrate WF. The notch part N may have a shape recessed from an outer circumference of the substrate WF toward a center of the substrate WF. For example, the notch part N may have a V-shape or U-shape when viewed in a plan view. The notch part N may be used to align the substrate WF during a semiconductor device fabrication process. For example, the notch part N may indicate the rotation degree of the substrate WF during a semiconductor device fabrication process.

According to example embodiments of the present inventive concept, the substrate WF may be rotated by ninety degrees after the exposure to the light is performed in the first shot region SR1 and before the exposure to the light is performed in the second shot region SR2. Thus, in a state in which the photomask M is fixed, an alignment angle of the substrate WF relative to the photomask M at the time of the exposure to the light for the first shot region SR1 and that at the time for the exposure to the light for the second shot region SR2 may be changed. For example, the degree of the substrate WF after the light exposure for the first shot region SR1 and before the light exposure for the first shot region SR2 may be ninety degrees.

According to example embodiments of the present inventive concept, a disposition direction of the photomask M may be fixed when the first pattern PT1 (of FIG. 6) and the second pattern PT2 (of FIG. 6) are exposed to the light. Relative to the photomask M, a disposition direction of the substrate WF at a time of exposing the first patten PT1 (of FIG. 6) to the light and a disposition direction of the substrate WF at a time of exposing the second pattern PT2 (of FIG. 6) to the light may cross. For example, an adjusted angle of the substrate WF may be ninety degrees relative to the photomask M. A position of the notch part N of the substrate WE at the time of exposing the first pattern PT1 (of FIG. 6) to the light and that at the time of exposing the second pattern PT2 (of FIG. 6) to the light may differ. Relative to the photomask M, an imaginary line connecting the center of the substrate WF and a center of the notch part N at the time of exposing the first pattern PT1 (of FIG. 6) to the light and that at the time of exposing the second pattern PT2 (of FIG. 6) to the light may perpendicularly cross each other.

FIG. 2 illustrates that exposure to the light is performed for one first shot region SR1 and one second shot region SR2 by using the photomask M in order to assist in understanding the present disclosure, but it is merely an example and not necessarily limited. The exposure to the light may be performed in a plurality of first shot regions SR1 and a plurality of second shot regions SR2 by using the photomask M.

The method for fabricating the semiconductor device according to example embodiments of the present inventive concept may further include measuring an overlay for the first shot region SR1 and measuring an overlay for the second shot region SR2. Measuring an overlay may include measuring whether a pattern is formed at a predetermined position, whether the pattern is aligned with another pattern formed in a previous process, or the like.

According to example embodiments of the present inventive concept, after exposing the first pattern PT1 (of FIG. 6) to the light in the first shot region SR1 and exposing the second pattern PT2 (of FIG. 6) to the light in the second shot region SR2, measurement of the overlay of the first pattern PT1 (of FIG. 6) and measurement of the overlay of the second pattern PT2 (of FIG. 6) may be performed. The overlay of the first pattern PT1 (of FIG. 6) and the overlay of the second pattern PT2 (of FIG. 6) may be individually measured. However, it is merely an example and not necessarily limited. For example, the overlay of the first pattern PT1 (of FIG. 6) and the overlay of the second pattern PT2 (of FIG. 6) may be measured simultaneously.

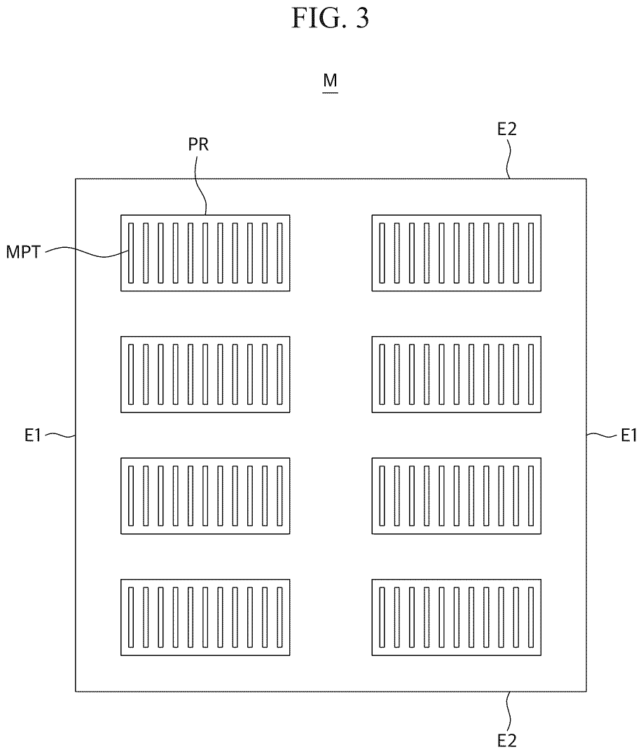

FIG. 3 is a diagram for describing a photomask of FIGS. 1 and 2.

Referring to FIG. 3, according to example embodiments of the present inventive concept, the photomask M may include a mask pattern MPT. The mask pattern MPT may be repeatedly disposed in an identical shape within the photomask M. The photomask M may include a plurality of pattern regions PR. The plurality of pattern regions PR may include the mask pattern MPT. The plurality of pattern regions PR may be separated from each other. The mask pattern MPT may be disposed in the plurality of pattern regions PR and might not be disposed between the plurality of pattern regions PR. For example, the mask pattern MPT disposed in one pattern region PR may be separated from the mask pattern MPT disposed in another pattern region PR of the photomask M.

According to example embodiments of the present inventive concept, the photomask M may include a first edge E1 and a second edge E2. The first edge E1 may face the first edge E1 disposed on an opposite side. The second edge E2 may cross the first edge E1. For example, the first edge E1 and the second edge E2 may perpendicularly intersect each other. The second edge E2 may face the second edge E2 disposed on an opposite side. Lengths of the first edge E1 and the second edge E2 may be equal. For example, the photomask M including the first edge E1 and the second edge E2 may have a square shape. However, it is merely an example and not necessarily limited. For example, the lengths of the first edge E1 and the second edge E2 may be different. For example, the photomask M including the first edge E1 and the second edge E2 may have a rectangular shape.

FIG. 3 illustrates that a plurality of mask patterns MPT is disposed in a pattern region PR, but it is merely an example and not necessarily limited. For example, one mask pattern MPT may be disposed in the pattern region PR.

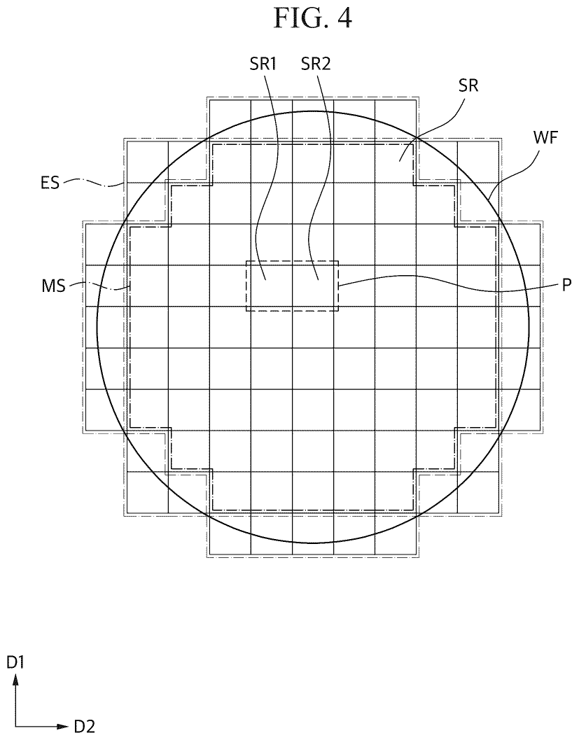

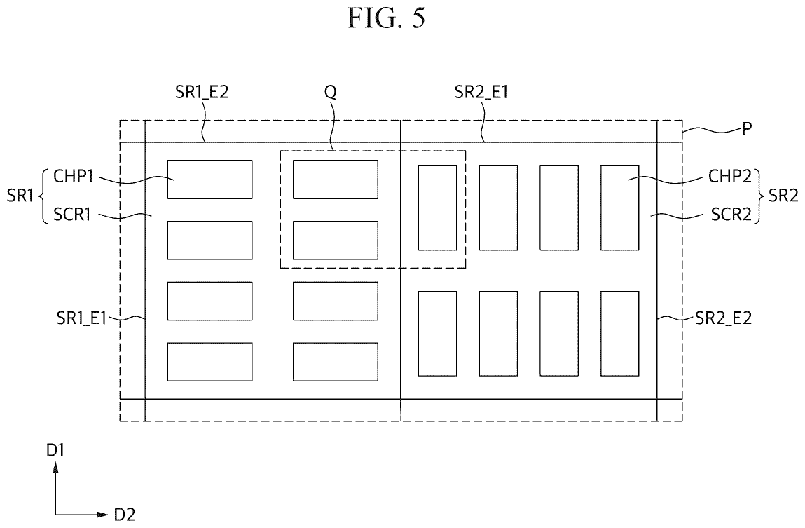

FIG. 4 is a diagram for describing a shot region of a substrate of a semiconductor device according to example embodiments of the present inventive concept. FIG. 5 is an example diagram illustrating an enlargement of part P of FIG. 4. FIG. 6 is an example diagram illustrating an enlargement of part Q of FIG. 5.

Referring to FIGS. 4 through 6, the substrate WF may include a plurality of shot regions SR. One shot region SR may be a unit region in which the substrate WF is patterned by using the photomask M. When exposure to light of the substrate WF by using the photomask M is performed one time, patterning for one shot region SR of the substrate WF may be performed. The plurality of shot regions SR may be disposed along a first direction D1 and a second direction D2.

According to example embodiments of the present inventive concept, the substrate WF may include a main section MS and an edge section ES. The main section MS may refer to a portion in which an entire area of a shot region SR is included in the substrate WF. For example, a pattern corresponding to the mask pattern MPT (of FIG. 3) of the photomask M (of FIG. 3) may be formed wholly in one shot region SR of the main section MS. The edge section ES may refer to a portion in which the entire area of the shot region SR is not included in the substrate WF and at least a portion thereof overlaps an outside of the substrate WF. For example, the pattern corresponding to the mask pattern MPT (of FIG. 3) of the photomask M (of FIG. 3) may be formed only partially in one shot region SR of the edge section ES, not wholly.

According to example embodiments of the present inventive concept, the shot region SR may be disposed throughout an entire region of the substrate WF. For example, the shot region SR may be disposed in the main section MS and the edge section ES. The shot region SR may include the first shot region SR1 and the second shot region SR2. The first shot region SR1 and the second shot region SR2 may be disposed in the main section MS.

According to example embodiments of the present inventive concept, the first shot region SR1 and the second shot region SR2 may be disposed to be adjacent to each other. The first shot region SR1 and the second shot region SR2 may be disposed to be adjacent to each other along the second direction D2. One of first shot edges SR1_E1 of the first shot region SR1 disposed along the first direction D1 and one of fourth shot edges SR2_E2 of the second shot region SR2 disposed along the first direction D1 may be in contact with each other.

According to example embodiments of the present inventive concept, the first shot region SR1 may include a first chip region CHP1 and a first scribe region SCR1. The first chip region CHP1 may be a region that is defined as the semiconductor device by sawing the first scribe region SCR1 after a semiconductor device fabrication process is completed. The first scribe region SCR1 may be a region that is sawed to be removed after the semiconductor device fabrication process is completed. The first scribe region SCR1 may separate a plurality of first chip regions CHP1. The first scribe region SCR1 may be disposed between the plurality of first chip regions CHP1. The first scribe region SCR1 may surround the plurality of first chip regions CHP1. For example, each of the first chip regions CHP1 may be in contact with the first scribe region SCR1 and might not be in contact with the other first chip regions CHP1.

According to example embodiments of the present inventive concept, the plurality of first chip regions CHP1 may be disposed in the first shot region SR1. The plurality of first chip regions CHP1 may be separated by the first scribe region SCR1. The first chip region CHP1 may correspond to the pattern region PR of the photomask M (of FIG. 3). In the first shot region SR1, four first chip regions CHP1 may be disposed along the first direction D1, and two first chip regions CHP1 may be disposed along the second direction D2. However, it is merely an example and not necessarily limited. The number or a shape of the plurality of first chip regions CHP1 which is disposed along the first direction D1 and the second direction D2 may vary depending on example embodiments.

According to example embodiments of the present inventive concept, the first shot region SR1 may include a first shot edge SR1_E1 and a second shot edge SR1_E2. The first shot edge SR1_E1 may correspond to the first edge E1 (of FIG. 3) of the photomask M (of FIG. 3). The first shot edge SR1_E1 may face another first shot edge SR1_E1 disposed on the opposite side. For example, the first shot edge SR1_E1 may be extended along the first direction D1 and spaced apart from the other in the second direction D2 to face the other. The second shot edge SR1_E2 may correspond to the second edge E2 (of FIG. 3) of the photomask M (of FIG. 3). The second shot edge SR1_E2 may face another second shot edge SR1_E2 disposed on the opposite side. For example, the second shot edge SR1_E2 may be extended along the second direction D2 and spaced apart from the other in the first direction D1 to face the other. The first shot edge SR1_E1 and the second shot edge SR1_E2 may cross.

According to example embodiments of the present inventive concept, the first pattern PT1 may be formed in the first shot region SR1. The first pattern PT1 may correspond to the mask pattern MPT (of FIG. 3) of the photomask M (of FIG. 3). That is, the first pattern PT1 may be exposed to the light in the first shot region SR1 by using the mask pattern MPT (of FIG. 3) of the photomask M (of FIG. 3).

According to example embodiments of the present inventive concept, the first pattern PT1 may be disposed to each of the plurality of first chip regions CHP1. For example, the first pattern PT1 may be formed so as to be extended along the first direction D1 in the first chip region CHP1. The first pattern PT1 may be formed adjacent to one another along the second direction D2. The first pattern PT1 may be extended along the first direction D1 in which the plurality of shot regions SR is disposed and may be spaced apart from another first pattern PT1 along the second direction D2 in which the plurality of shot regions SR is disposed.

According to example embodiments of the present inventive concept, the second shot region SR2 may include a second chip region CHP2 and a second scribe region SCR2. The second chip region CHP2 may be a region that is defined as the semiconductor device by sawing the second scribe region SCR2 after the semiconductor device fabrication process is completed. The second scribe region SCR2 may be a region that is sawed to be removed after the semiconductor device fabrication process is completed. The second scribe region SCR2 may separate a plurality of second chip regions CHP2. The second scribe region SCR2 may be disposed between the plurality of second chip regions CHP2. The second scribe region SCR2 may surround the plurality of second chip regions CHP2. For example, each of the second chip regions CHP2 may be in contact with the second scribe region SCR2 and might not be in contact with the other second chip regions CHP2. For example, the second scribe region SCR2 may divide the plurality of the second chip regions CHP2.

According to example embodiments of the present inventive concept, the plurality of second chip regions CHP2 may be disposed in the second shot region SR2. The plurality of second chip regions CHP2 may be separated by the second scribe region SCR2. The second chip region CHP2 may correspond to the pattern region PR of the photomask M (of FIG. 3). In the second shot region SR2, two second chip regions CHP2 may be disposed along the first direction D1, and four second chip regions CHP2 may be disposed along the second direction D2. However, it is merely an example and not necessarily limited. The number or a shape of the plurality of second chip regions CHP2 which is disposed along the first direction D1 and the second direction D2 may vary depending on example embodiments.

According to example embodiments of the present inventive concept, the second shot region SR2 may include a third shot edge SR2_E1 and a fourth shot edge SR2_E2. The third shot edge SR2_E1 may correspond to the first edge E1 (of FIG. 3) of the photomask M (of FIG. 3). The third shot edge SR2_E1 may face another third shot edge SR2_E1 disposed on the opposite side. For example, the third shot edge SR2_E1 may be extended along the second direction D2 and spaced apart from the other along the first direction D1 to face the other. The fourth shot edge SR2_E2 may correspond to the second edge E2 (of FIG. 3) of the photomask M (of FIG. 3). The fourth shot edge SR2_E2 may face another fourth shot edge SR2_E2, which is disposed on the opposite side. For example, the fourth shot edge SR2_E2 may be extended along the first direction D1 and spaced apart from the other along the second direction D2 to face the other. The third shot edge SR2_E1 and the fourth shot edge SR2_E2 may cross.

According to example embodiments of the present inventive concept, the second pattern PT2 may be formed in the second shot region SR2. The second pattern PT2 may correspond to the mask pattern MPT (of FIG. 3) of the photomask M (of FIG. 3). That is, the second pattern PT2 may be exposed to the light in the second shot region SR2 by using the mask pattern MPT (of FIG. 3) of the photomask M (of FIG. 3).

According to example embodiments of the present inventive concept, the second pattern PT2 may be disposed to each of the plurality of second chip regions CHP2. For example, the second pattern PT2 may be formed so as to be extended along the second direction D2 in the second chip region CHP2. The second pattern PT2 may be arranged and formed in the first direction D1. The second direction D2 in which the second pattern PT2 is extended may perpendicularly cross the first direction D1 in which the first pattern PT1 is extended. The second pattern PT2 may be extended along the second direction D2 in which the plurality of shot regions SR is disposed and may be spaced apart from another along the first direction D1 in which the plurality of shot regions SR is disposed.

According to example embodiments of the present inventive concept, one edge of the first scribe region SCR1 and one edge of the second scribe region SCR2 may be disposed in contact with each other on the substrate WF. The first scribe region SCR1 may include the first shot edge SR1_E1 and the second shot edge SR1_E2. The second scribe region SCR2 may include the third shot edge SR2_E1 and the fourth shot edge SR2_E2. The first shot edge SR1_E1 of the first scribe region SCR1 and the fourth shot edge SR2_E2 of the second scribe region SCR2 may be disposed in contact with each other.

According to example embodiments of the present inventive concept, a test pattern TP may be disposed in the first shot region SR1 and the second shot region SR2. The test pattern TP may be disposed in the first scribe region SCR1 and the second scribe region SCR2. The test pattern TP may include a test element group (TEG) circuit. The test element group (TEG) circuit may include a circuit for testing electrical characteristics of the first chip region CHP1 and the second chip region CHP2.

According to example embodiments of the present inventive concept, the first shot edge SR1_E1 of the first shot region SR1 and the third shot edge SR2_E1 of the second shot region SR2 may cross. For example, an extension direction of the first shot edge SR1_E1 and an extension direction of the third shot edge SR2_E1 may perpendicularly cross each other. Although corresponding to the first edge E1 (of FIG. 1) of the photomask M (of FIG. 3), all of the first shot edge SR1_E1 of the first shot region SR1 and the third shot edge SR2_E1 of the second shot region SR2 may be disposed so as to cross and not to be extended in an identical direction. For example, the first shot edge SR1_E1 of the first shot region SR1 may extend along the first direction D1, and the third shot edge SR2_E1 of the second shot region SR2 may extend along the second direction D2. This may be because an alignment of the substrate WF relative to the photomask M at a time of the exposure to the light for the first shot region SR1 differs from an alignment at a time of the exposure to the light for the second shot region SR2, with two alignments crossing at a right angle.

According to example embodiments of the present inventive concept, an extension direction of the first pattern PT1 of the first shot region SR1 and an extension direction of the second pattern PT2 of the second shot region SR2 may cross. For example, the extension direction of the first pattern PT1 and the extension direction of the second pattern PT2 may perpendicularly cross each other. Although being formed by using the mask pattern MPT (of FIG. 3) of the photomask M (of FIG. 3), all of the first pattern PT1 of the first shot region SR1 and the second pattern PT2 of the second shot region SR2 may be disposed so as to cross and not to be extended in an identical direction. For example, the first pattern PT1 of the first shot region SR1 may extend along the first direction D1, and the second pattern PT2 of the second shot region SR2 may extend along the second direction D2. This may be because the alignment angle of the substrate WF relative to the photomask M at the time of the exposure to the light for the first shot region SR1 and that at the time of the exposure to the light for the second shot region SR2 perpendicularly cross. For example, the substrate WF may be rotated ninety degrees before exposure to light for the second shot region SR2, following exposure for the first shot region SR1, while the photomask M remains fixed.

According to example embodiments of the present inventive concept, a shape in which the first chip region CHP1 is disposed in the first shot region SR1 and a shape in which the second chip region CHP2 is disposed in the second shot region SR2 may differ. In the first shot region SR1, the four first chip regions CHP1 may be disposed along the first direction D1, and the two first chip regions CHP1 may be disposed along the second direction D2. In the second shot region SR2, the two second chip regions CHP2 may be disposed along the first direction D1, and the four second chip regions CHP2 may be disposed along the second direction D2.

According to example embodiments of the present inventive concept, each of the shape in which the first chip region CHP1 is disposed in the first shot region SR1 and the shape in which the second region CHP2 is disposed in the second shot region SR2 may be identical to a shape in which the pattern region PR (of FIG. 3) of the photomask M (of FIG. 3) is disposed. However, the shape in which the first chip region CHP1 is disposed in the first shot region SR1 and the shape in which the second region CHP2 is disposed in the second shot region SR2 may be disposed in a relationship in which each is rotated by ninety degrees from another. This may be because the alignment angle of the substrate WF relative to the photomask M at the time of the exposure to the light for the first shot region SR1 and that at the time of the exposure to the light for the second shot region SR2 perpendicularly cross.

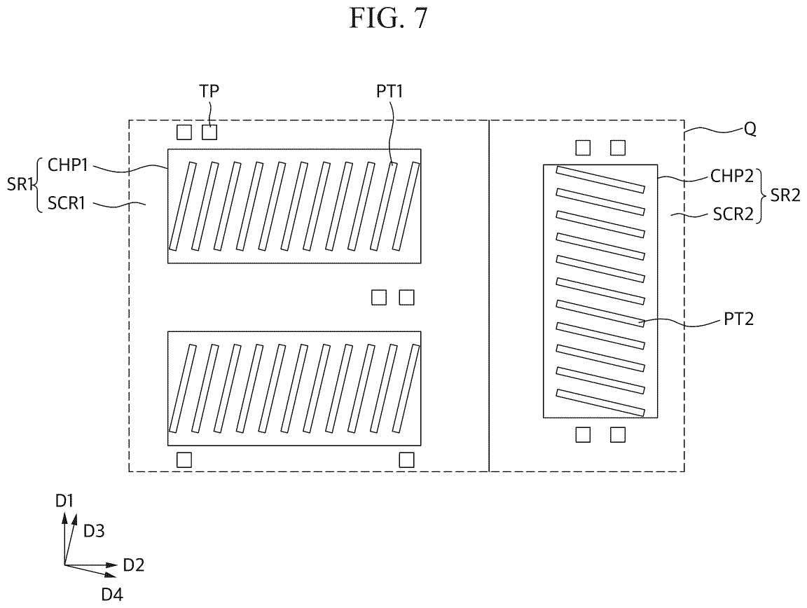

FIG. 7 is an example diagram illustrating an enlargement of part Q of FIG. 5 for describing a method for fabricating a semiconductor device according to example embodiments of the present inventive concept. In order to assist in understanding the present disclosure, a description will mainly focus on a point different from that described above with reference to FIGS. 4 through 6. To the extent that an element has not been described in detail, it may be assumed that the element is at least similar to corresponding elements that have been described in FIGS. 4 through 6.

Referring to FIG. 7, the first pattern PT1 and the second pattern PT2 may be extended along a direction different from a direction in which the plurality of shot regions SR (of FIG. 4) is disposed. The first pattern PT1 and the second pattern PT2 may not be extended along the first direction D1 and the second direction D2 in which the plurality of shot regions SR (of FIG. 4) is disposed.

According to example embodiments of the present inventive concept, the first pattern PT1 may be extended along a third direction D3 crossing the first direction D1 and the second direction D2 in which the plurality of shot regions SR (of FIG. 4) is disposed. The first pattern PT1 may be spaced apart from another along the second direction D2. The third direction D3 may cross the first direction D1 and the second direction D2 at a non-perpendicular angle. For example, the third direction D3 may cross the first direction D1 and the second direction D2 at an acute angle or an obtuse angle.

According to example embodiments of the present inventive concept, the second pattern PT2 may be extended along a fourth direction D4 crossing the first direction D1 and the second direction D2 in which the plurality of shot regions SR (of FIG. 4) is disposed. The second pattern PT2 may be spaced apart from another in the first direction D1. The fourth direction D4 may cross the first direction D1 and the second direction D2 at a non-perpendicular angle. For example, the fourth direction D4 may cross the first direction D1 and the second direction D2 at an acute angle or an obtuse angle. The fourth direction D4 may perpendicularly cross the third direction D3.

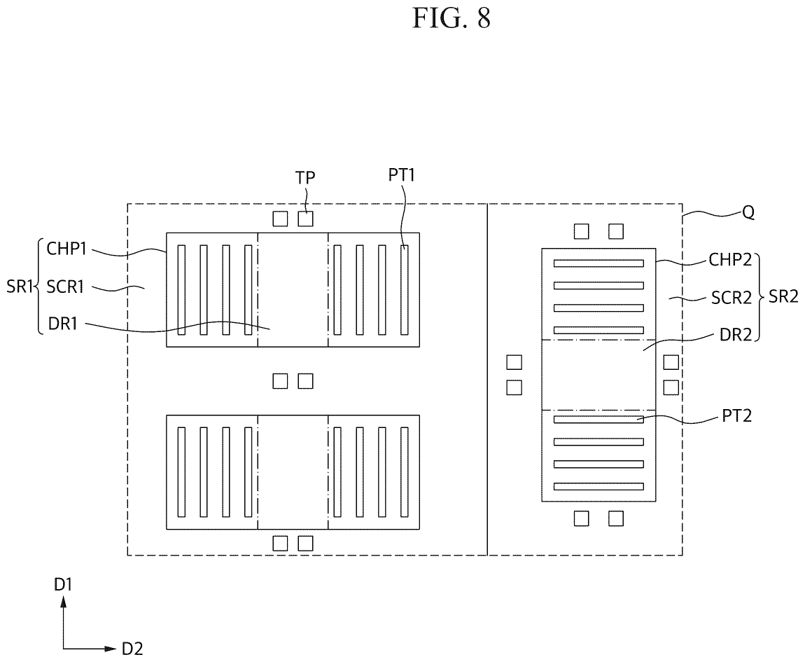

FIG. 8 is an example diagram illustrating an enlargement of the part Q of FIG. 5 for describing a method for fabricating a semiconductor device according to still some example embodiments of the present inventive concept. In order to assist in understanding the present disclosure, a description will mainly focus on a point different from that described above with reference to FIGS. 4 through 6. To the extent that an element has not been described in detail, it may be assumed that the element is at least similar to corresponding elements that have been described in FIGS. 4 through 6.

Referring to FIG. 8, the first shot region SR1 may include a first dummy region DR1. The second shot region SR2 may include a second dummy region DR2.

According to example embodiments of the present inventive concept, the first dummy region DR1 may be a region in which the first pattern PT1 is not formed in the first chip region CHP1. The first pattern PT1 may not be formed in the first dummy region DR1. The first dummy region DR1 may be formed between first patterns PT1.

According to example embodiments of the present inventive concept, the second dummy region DR2 may be a region in which the second pattern PT2 is not formed in the second chip region CHP2. The second pattern PT2 may not be formed in the second dummy region DR2. The second dummy region DR2 may be formed between second patterns PT2.

According to example embodiments of the present inventive concept, the test pattern TP may be disposed to be adjacent to the first dummy region DR1 and the second dummy region DR2. For example, the test pattern TP may be disposed to be spaced apart from the first dummy region DR1 in the first direction D1 in the first shot region SR1. The test pattern TP may be disposed to be spaced apart from the second dummy region DR2 in the second direction D2 in the second shot region SR2.

According to example embodiments of the present inventive concept, a possibility of warpage of the substrate WF (of FIG. 5) in the first dummy region DR1, where the first pattern PT1 is not disposed, and a nearby region may be relatively lower than that of warpage of the substrate WF (of FIG. 5) around the first pattern PT1. A possibility of warpage of the substrate WF (of FIG. 5) in the second dummy region DR2, where the second pattern PT2 is not disposed, and a nearby region may be relatively lower than that of warpage of the substrate WF (of FIG. 5) around the second pattern PT2. Thus, a danger that the test pattern TP disposed to be adjacent to the first dummy region DR1 and the second dummy region DR2 is damaged due to warpage of the substrate WF (of FIG. 5) may be reduced.

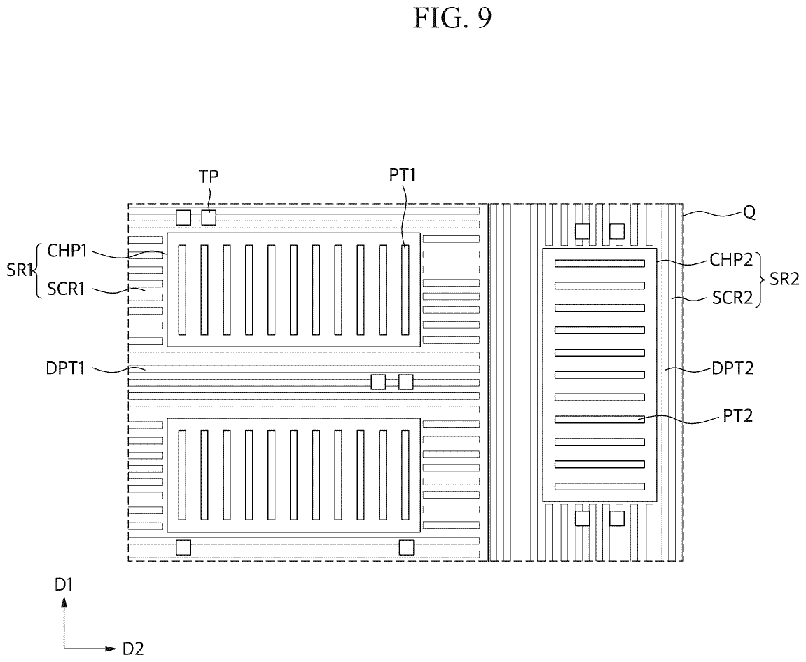

FIG. 9 is an example diagram illustrating an enlargement of the part Q of FIG. 5 for describing a method for fabricating a semiconductor device according to example embodiments of the present inventive concept. In order to assist in understanding the present disclosure, a description will mainly focus on a point different from that described above with reference to FIGS. 4 through 6. To the extent that an element has not been described in detail, it may be assumed that the element is at least similar to corresponding elements that have been described in FIGS. 4 through 6.

Referring to FIG. 9, the method for fabricating the semiconductor device according to example embodiments of the present inventive concept may further include exposing a first dummy pattern DPT1 to light in the first shot region SR1. The first dummy pattern DPT1 may be formed in the first scribe region SCR1 of the first shot region SR1. The method for fabricating the semiconductor device according to example embodiments of the present inventive concept may further include exposing a second dummy pattern DPT2 to the light in the second shot region SR2. The second dummy pattern DPT2 may be formed in the second scribe region SCR2 of the second shot region SR2.

According to example embodiments of the present inventive concept, an extension direction of the first dummy pattern DPT1 and an extension direction of the first pattern PT1 may cross. For example, the first dummy pattern DPT1 may be extended along the second direction D2, and the first pattern PT1 may be extended along the first direction D1. The first dummy pattern DPT1 may be formed to be spaced apart from another along the first direction D1.

According to example embodiments of the present inventive concept, the first dummy pattern DPT1 may relieve warpage of the substrate WF (of FIG. 4) due to a plurality of first patterns PT1 extended along the first direction D1 and repeatedly formed so as to be spaced from each other along the second direction D2. For example, the first dummy pattern DPT1 may reduce warpage of the substrate WF caused by the plurality of first patterns PT1, which extends at ninety degrees angle from the first dummy pattern DPT1 without being in contact. As being formed so as to be extended in a direction crossing a direction in which the first pattern PT1 is extended, the first dummy pattern DPT1 may relieve the warpage of the substrate WF (of FIG. 4) due to the plurality of first patterns PT1 which is extended in an identical direction.

According to example embodiments of the present inventive concept, an extension direction of the second dummy pattern DPT2 and an extension direction of the second pattern PT2 may cross. For example, the second dummy pattern DPT2 may be extended along the first direction D1, and the second pattern PT2 may be extended along the second direction D2. The second dummy pattern DPT2 may be disposed to be spaced apart from another along the second direction D2.

According to example embodiments of the present inventive concept, the second dummy pattern DPT2 may relieve warpage of the substrate WF (of FIG. 4) due to a plurality of second patterns PT2 extended in the second direction D2 and repeatedly formed so as to be spaced from each other in the first direction D1. For example, the second dummy pattern DPT2 may reduce warpage of the substrate WF caused by the plurality of second patterns PT2, which extends at ninety degrees angle from the second dummy pattern DPT2 without being in contact. As being formed so as to be extended in a direction crossing a direction in which the second pattern PT2 is extended, the second dummy pattern DPT2 may relieve the warpage of the substrate WF (of FIG. 4) due to the plurality of second patterns PT2 which is extended in an identical direction.

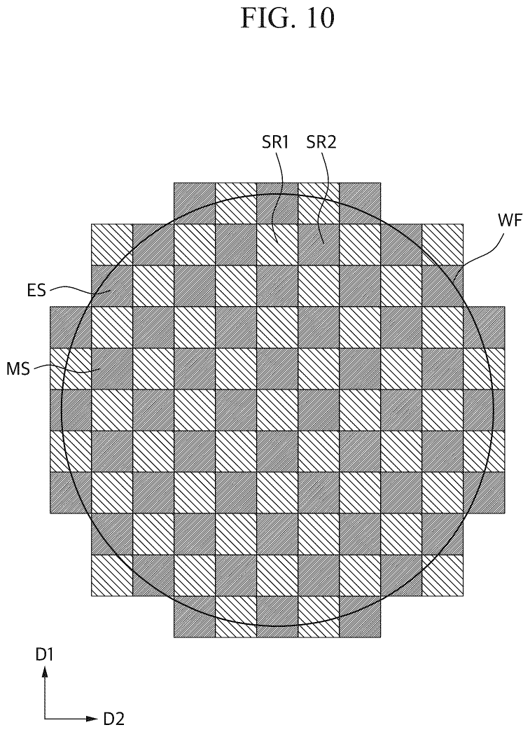

FIGS. 10 through 13 are diagrams for describing a method of fabricating a semiconductor device according to example embodiments of the present inventive concept. In order to assist in understanding the present disclosure, a description will mainly focus on a point different from that described above with reference to FIGS. 4 through 6. To the extent that an element has not been described in detail, it may be assumed that the element is at least similar to corresponding elements that have been described in FIGS. 4 through 6.

Referring to FIG. 10, the first shot region SR1 and the second shot region SR2 may be alternately disposed along the first direction D1 and the second direction D2. Along the first direction D1, the first shot region SR1 and the second shot region SR2 may be alternately disposed. Along the second direction D2, the first shot region SR1 and the second shot region SR2 may be alternately disposed. An alternating pattern of the first shot region SR1 and the second shot region SR2 along the first and second directions D1 and D2 may create a grid-like structure, with each of the first and second shot region SR1 and SR2 spaced apart from the adjacent one. Each of the first shot region SR1 and the second shot region SR2 may have a square shape.

According to example embodiments of the present inventive concept, the first shot region SR1 and the second shot region SR2 may be shot regions SR (of FIG. 4) in which identical patterns exposed to light by using one photomask M (of FIG. 3) including the mask pattern MPT (of FIG. 3) are not disposed in an identical direction and that individually includes the first pattern PT1 (of FIG. 6) and the second pattern PT2 (of FIG. 6) which are formed so as to perpendicularly cross each other.

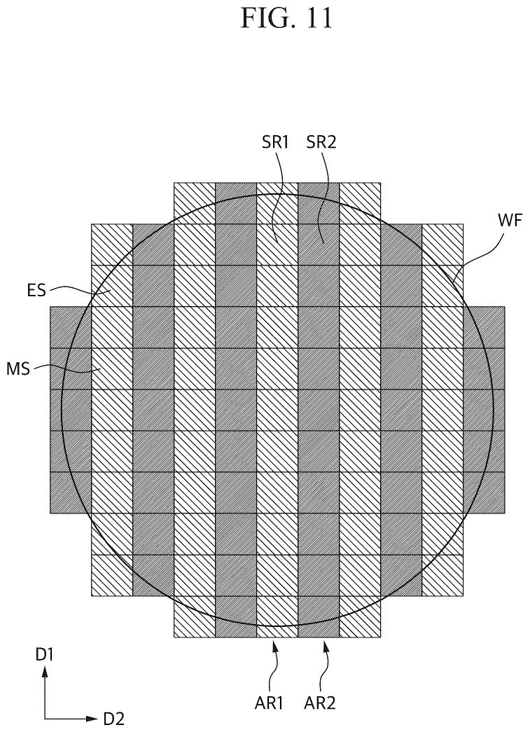

Referring to FIG. 11, the plurality of first shot regions SR1 may be disposed to be adjacent to each other along the first direction D1. Along the first direction D1, the plurality of first shot regions SR1 may be arranged. For example, the first shot regions SR1 may be arranged consecutively along the first direction D1, with each region placed directly next to the other, forming a continuous sequence of the first shot regions SR1. Along the second direction D2, two first shot regions SR1 may be spaced apart from each other with the second shot region SR2 in between. The plurality of second shot regions SR2 may be disposed to be adjacent to each other along the first direction D1. Along the first direction D1, the plurality of second shot regions SR2 may be arranged. In the second direction D2, two second shot regions SR2 may be spaced apart from each other with the first shot region SR1 in between. For example, an arrangement creates a structure where the first shot regions SR1 are grouped together along the first direction D1, while the spacing between the first shot regions SR1 along the second direction is filled by the second shot regions SR2, resulting in an alternating pattern of the first shot regions SR1 and the second shot regions SR2 along the second direction D2.

According to example embodiments of the present inventive concept, the substrate WF may include a first array AR1 and a second array AR2. The first array AR1 may include the plurality of first shot regions SR1 disposed along the first direction D1. The second array AR2 may include the plurality of second shot regions SR2 disposed along the first direction D1. The first array AR1 and the second array AR2 may be alternately disposed along the second direction D2.

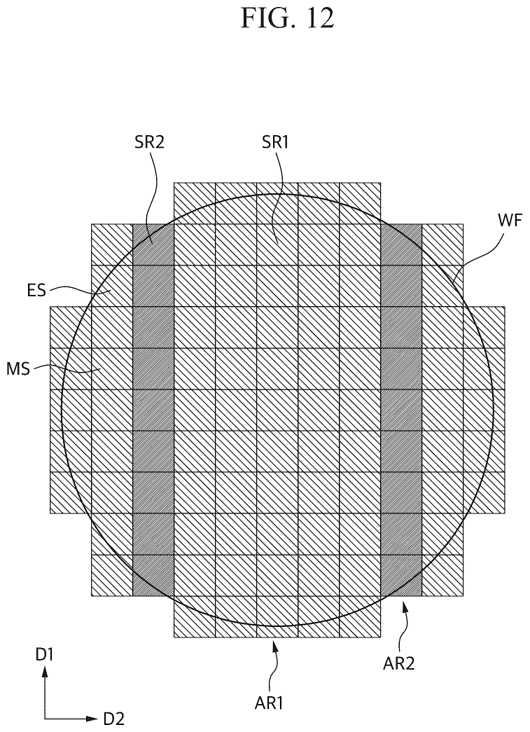

Referring to FIG. 12, a plurality of first arrays AR1 may be disposed to be adjacent to each other along the second direction D2. The second array AR2 may be disposed between two first arrays AR1 along the second direction D2.

According to example embodiments of the present inventive concept, the plurality of first shot regions SR1 may be disposed so as to be adjacent to each other along the second direction D2. The second shot region SR2 may be disposed between two first shot region SR1 along the second direction D2.

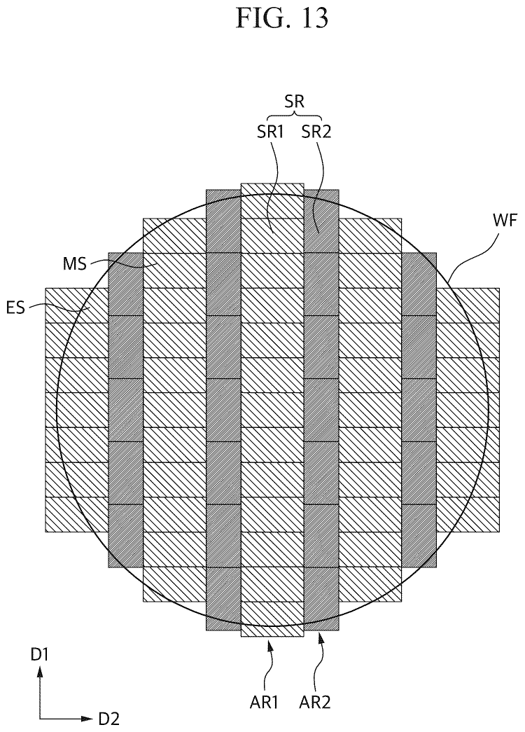

Referring to FIG. 13, the shot region SR may have a rectangular shape. The shot region SR may have the rectangular shape which includes a long side and a short side extended along the first direction D1 and the second direction D2.

According to example embodiments of the present inventive concept, the first shot region SR1 may have an edge of a short side extended in the first direction D1 and an edge of a long side extended in the second direction D2. The second shot region SR2 may have an edge of a long side extended in the first direction D1 and an edge of a short side extended in the second direction D2.

According to example embodiments of the present inventive concept, the plurality of first shot regions SR1 may be disposed in the first direction D1 to form the first array AR1. The plurality of second shot regions SR2 may be disposed along the first direction D1 to form the second array AR2. The first array AR1 and the second array AR2 may be alternately disposed along the second direction D2. Along the second direction D2, a width of the first array AR1 and a width of the second array AR2 may differ. For example, along the second direction D2, the width of the first array AR1 may be larger than the width of the second array AR2.

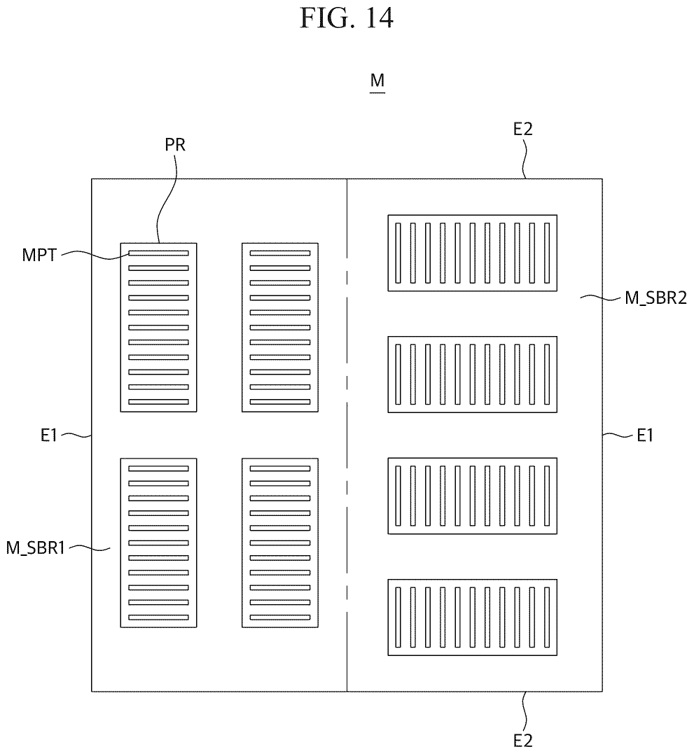

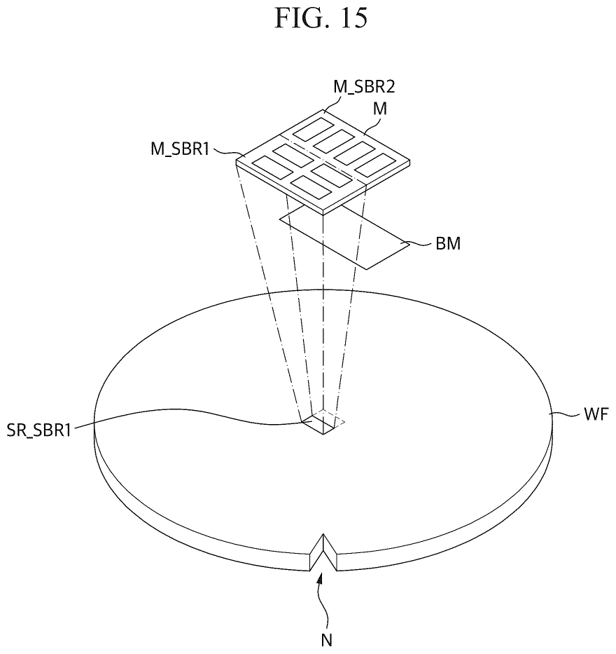

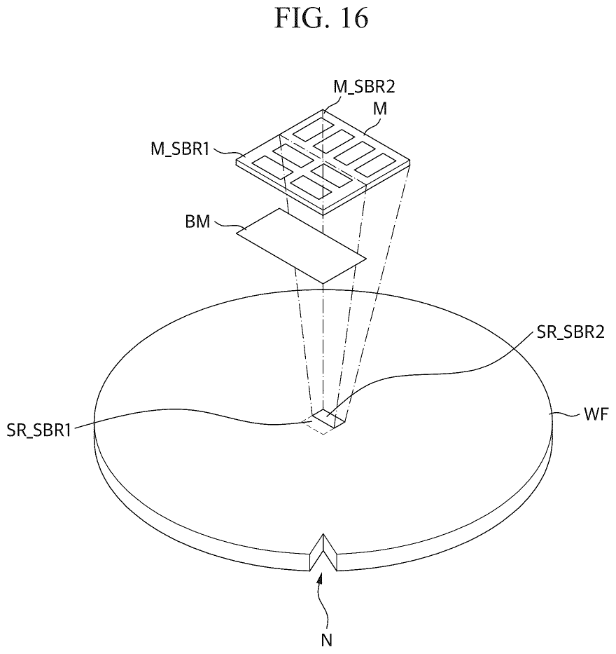

FIG. 14 is a diagram for describing a photomask according to example embodiments of the present inventive concept. FIGS. 15 and 16 are diagrams illustrating an intermediate operation for describing a method for fabricating a semiconductor device according to example embodiments of the present inventive concept. In order to assist in understanding the method for fabricating the semiconductor device according example embodiments of the present inventive concept, a description will mainly focus on a point different from that described above with reference to FIGS. 1 through 3. To the extent that an element has not been described in detail, it may be assumed that the element is at least similar to corresponding elements that have been described in FIGS. 1 through 3.

Referring to FIG. 14, the photomask M may include a first mask sub-region M_SBR1 and a second mask sub-region M_SBR2. The plurality of pattern regions PR may be disposed in different shapes in the first mask sub-region M_SBR1 and the second mask sub-region M_SBR2. The first mask sub-region M_SBR1 and the second mask sub-region M_SBR2 of the photomask M may have an asymmetric structure.

According to example embodiments of the present inventive concept, an extension direction of the mask pattern MPT in the first mask sub-region M_SBR1 and an extension direction of the mask pattern MPT in the second mask sub-region M_SBR2 may cross each other. In the first mask sub-region M_SBR1, the mask pattern MPT may be extended along a direction in which the second edge E2 is extended. In the second mask sub-region M_SBR2, the mask pattern MPT may be extended along a direction in which the first edge E1 is extended.

According to example embodiments of the present inventive concept, in the first mask sub-region M_SBR1, two of the plurality of pattern regions PR may be disposed along an extension direction of the first edge E1, and two of the plurality of pattern regions PR may be disposed along an extension direction of the second edge E2. For example, two pattern regions PR may be disposed side by side on an upper line, and two pattern regions PR may be disposed side by side on a lower line, forming a multi-row configuration. In the first mask sub-region M_SBR1, long sides of the plurality of pattern regions PR may be disposed along the extension direction of the first edge E1, and short sides of the plurality of pattern regions PR may be disposed along the extension direction of the second edge E2. For example, the pattern regions PR in the first mask sub-region M_SBR1 may be rectangular shape, and the longer side of each rectangle may be oriented along the first edge E1, and the shorter side may be aligned with the second edge E2.

According to example embodiments of the present inventive concept, in the second mask sub-region M_SBR2, four of the plurality of pattern regions PR may be disposed along the extension direction of the first edge E1, and one of the plurality of pattern regions PR may be disposed along the extension direction of the second edge E2. In the second mask sub-region M_SBR2, the long sides of the plurality of pattern regions PR may be disposed along the extension direction of the second edge E2, and the short sides of the plurality of pattern regions PR may be disposed along the extension direction of the first edge E1. For example, the pattern regions PR of the second mask sub-region M_SBR2 may be rectangular shape, and the longer side of each rectangle may be oriented along the second edge E2, and the shorter side may be aligned with the first edge E1.

Referring to FIG. 15, the method for fabricating the semiconductor device according to example embodiments of the present inventive concept may include forming a pattern in a first shot sub-region SR_SBR1 of the substrate WF by using the photomask M. The first shot sub-region SR_SBR1 may correspond to the first mask sub-region M_SBR1. When the pattern is formed in the first shot sub-region SR_SBR1, a block mask BM may be used, so that the mask pattern MPT (of FIG. 14) in the second mask sub-region M_SBR2 of the photomask M might not pattern on the substrate WF.

Then, referring to FIG. 16, the method for fabricating the semiconductor device according to example embodiments of the present inventive concept may include forming a pattern in a second shot sub-region SR_SBR2 of the substrate WF by using the photomask M. The second shot sub-region SR_SBR2 and the first shot sub-region SR_SBR1 may be disposed to be adjacent to each other. The second shot sub-region SR_SBR2 may correspond to the second mask sub-region M_SBR2. When the pattern is formed in the second shot sub-region SR_SBR2, the block mask BM may be used, so that the substrate WF might not be patterned with the mask pattern MPT (of FIG. 14) of the first mask sub-region M_SBR1 of the photomask M.

Referring back to FIGS. 15 and 16, the method for fabricating the semiconductor device may include forming a pattern in the first shot sub-region SR_SBR1 and the second shot sub-region SR_SBR2 while an alignment angle of the substrate WF relative to the photomask M is fixed without rotating the substrate WF by ninety degrees. The notch part N of the substrate WF at a time of exposure to light for the first shot sub-region SR_SBR1 and the notch part N of the substrate WF at a time of exposure to the light for the second shot sub-shot region SR_SBR2 may be fixed at an identical position on an identical plane.

FIGS. 15 and 16 illustrate that the first mask sub-region M_SBR1 and the second mask sub-region M_SBR2 of the photomask M are individually exposed to the light so that the first shot sub-region SR_SBR1 and the second shot sub-region SR_SBR2 are formed, but it is merely an example and not necessarily limited. For example, the first mask sub-region M_SBR1 and the second mask sub-region M_SBR2 of the photomask M may be simultaneously exposed to the light without using the block mask BM, so that the first shot sub-region SR_SBR1 and the second shot sub-region SR_SBR2 of the substrate WF may be simultaneously patterned.

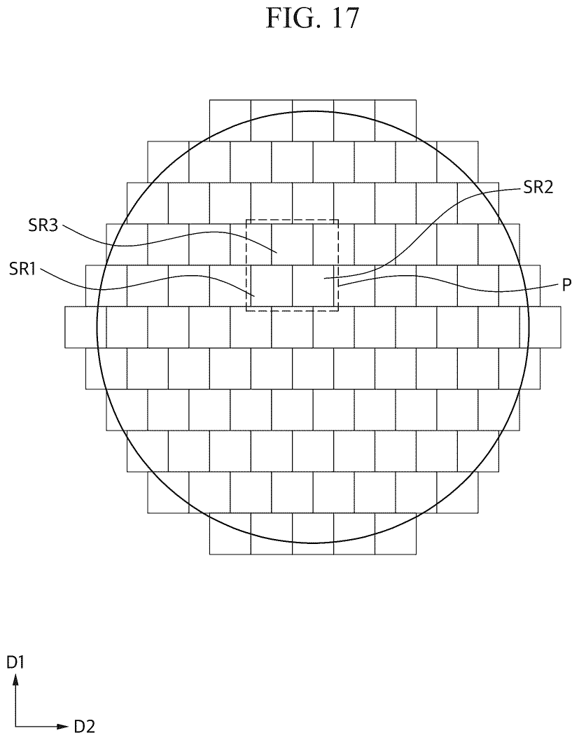

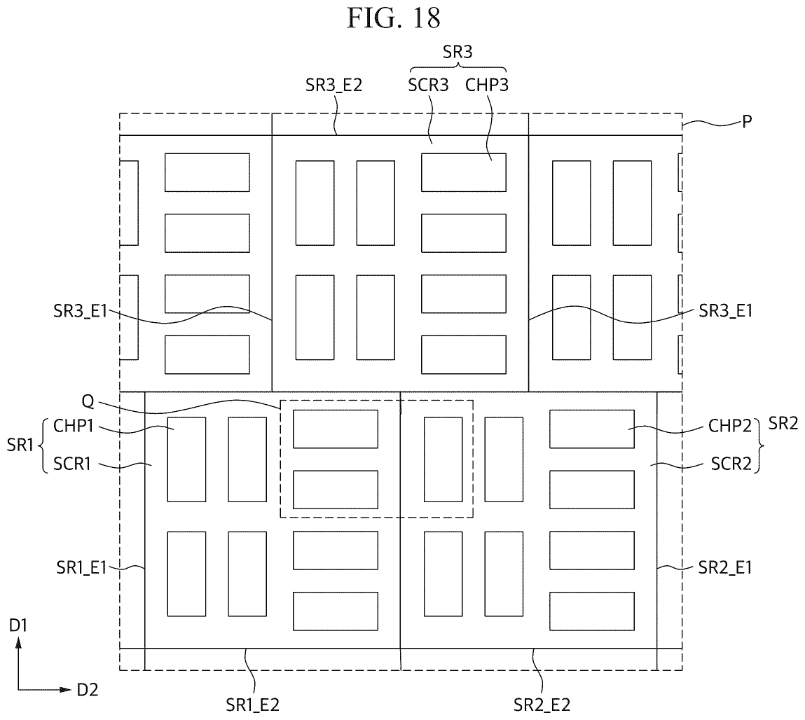

FIG. 17 is a diagram for describing a shot region of a substrate of a semiconductor device according to example embodiments of the present inventive concept. FIG. 18 is an example diagram illustrating an enlargement of part P of FIG. 17. For reference, part Q of FIG. 18 is identical to that illustrated in FIG. 6. In order to assist in understanding the present disclosure, a description will mainly focus on a point different from that described above with reference to FIGS. 4 through 6. To the extent that an element has not been described in detail, it may be assumed that the element is at least similar to corresponding elements that have been described in FIGS. 4 through 6.

Referring to FIGS. 17 and 18, a plurality of shot regions may be disposed to be staggered in the first direction D1. For example, a third shot region SR3 may be disposed so as to partially overlap each of the first shot region SR1 and the second shot region SR2.

According to example embodiments of the present inventive concept, a portion of the third shot region SR3, which corresponds to the first mask sub-region M_SBR1 (of FIG. 14) of the photomask M (of FIG. 14) (e.g., a left half region of the third shot region SR3 of FIG. 18), may overlap a portion of the first shot region SR1, which corresponds to the second mask sub-region M_SBR2 (of FIG. 14) of the photomask M (of FIG. 14) (e.g., a right half region of the first shot region SR1 of FIG. 18), in the first direction D1.

According to example embodiments of the present inventive concept, a portion of the third shot region SR3, which corresponds to the second mask sub-region M_SBR2 (of FIG. 14) of the photomask M (of FIG. 14) (e.g., a right half region of the third shot region SR3 of FIG. 18), may overlap a portion of the second shot region SR2, which corresponds to the first mask sub-region M_SBR1 (of FIG. 14) of the photomask M (of FIG. 14) (e.g., a left half region of the second shot region SR2 of FIG. 18), in the first direction D1. For example, the third shot region SR3, the first shot region SR1, and the second shot region SR2 may be arranged in a stacked formation, with the third shot region SR3 partially overlapping the first and second shot regions SR1 and SR2 along a vertical axis. The first and second shot regions SR1 and SR2 may be disposed next to each other. The third shot region SR3 may overlap the top and bottom portion of the first and second shot regions SR1 and SR2, creating a vertical layer where the third shot region SR3 is centered above the first and second shot regions SR1 and SR2.

According to example embodiments of the present inventive concept, a pattern disposed in the portion of the third shot region SR3, which corresponds to the first mask sub-region M_SBR1 (of FIG. 14) of the photomask M (of FIG. 14), may be extended along the second direction D2. A pattern disposed in the portion of the third shot region SR3, which corresponds to the second mask sub-region M_SBR2 (of FIG. 14) of the photomask M (of FIG. 14), may be extended along the first direction D1.

According to example embodiments of the present inventive concept, the pattern disposed in the portion of the third shot region SR3, which corresponds to the first mask sub-region M_SBR1 (of FIG. 14) of the photomask M (of FIG. 14), may perpendicularly cross the first pattern PT1 (of FIG. 6) which is disposed in the portion of the first shot region SR1, which corresponds to the second mask sub-region M_SBR2 (of FIG. 14) of the photomask M (of FIG. 14).

According to example embodiments of the present inventive concept, the pattern disposed in the portion of the third shot region SR3, which corresponds to the second mask sub-region M_SBR2 (of FIG. 14) of the photomask M (of FIG. 14), may perpendicularly cross the second pattern PT2 (of FIG. 6) which is disposed in a portion of the second shot region SR2, which corresponds to the first mask sub-region M_SBR1 (of FIG. 14) of the photomask M (of FIG. 14).

According to example embodiments of the present inventive concept, a fifth shot edge SR3_E1 and a sixth shot edge SR3_E2 of the third shot region SR3 may correspond to the first edge E1 (of FIG. 14) and the second edge E2 (of FIG. 14) of the photomask M (of FIG. 14), respectively.

According to example embodiments of the present inventive concept, the fifth shot edge SR3_E1 of the third shot region SR3 might not be disposed with the first shot edge SR1_E1 of the first shot region SR1 and the third shot edge SR2_E1 of the second shot region SR2 in a straight line. The fifth shot edge SR3_E1 of the third shot region SR3 may be disposed to be staggered from the first shot edge SR1_E1 of the first shot region SR1 and the third shot edge SR2_E1 of the second shot region SR2. The fifth shot edge SR3_E1 of the third shot region SR3 may be extended along a direction identical to those of the first shot edge SR1_E1 of the first shot region SR1 and the third shot edge SR2_E1 of the second shot region SR2.

According to example embodiments, the sixth shot edge SR3_E2 of the third shot region SR3 may be in contact with a portion of each of the second shot edge SR1_E2 of the first shot region SR1 and the fourth shot edge SR2_E2 of the second shot region SR2. The sixth shot edge SR3_E2 of the third shot region SR3 may be extended along a direction identical to those of the second shot edge SR1_E2 of the first shot region SR1 and the fourth shot edge SR2_E2 of the second shot region SR2.

According to example embodiments of the present inventive concept, the first shot edge SR1_E1 of the first shot region SR1 and the third shot edge SR2_E1 of the second shot region SR2 may be in contact with each other. The first shot edge SR1_E1 of the first shot region SR1 and the third shot edge SR2_E1 of the second shot region SR2 might not cross and may be disposed along an identical direction. The first shot edge SR1_E1 of the first shot region SR1 and the third shot edge SR2_E1 of the second shot region SR2 may be extended along the first direction D1.

According to example embodiments of the present inventive concept, the second shot edge SR1_E2 of the first shot region SR1 and the fourth shot edge SR2_E2 of the second shot region SR2 might not cross. The second shot edge SR1_E2 of the first shot region SR1 and the fourth shot edge SR2_E2 of the second shot region SR2 may be disposed in a straight line. The second shot edge SR1_E2 of the first shot region SR1 and the fourth shot edge SR2_E2 of the second shot region SR2 may be extended along the second direction D2.

According to example embodiments of the present inventive concept, a portion of the first shot region SR1 (e.g., a left half region of the first shot region SR1 of FIG. 18) may be patterned with the first mask sub-region M_SBR1 (of FIG. 14) of the photomask M (of FIG. 14) to be formed. A remaining portion of the first shot region SR1 (e.g., the right half region of the first shot region SR1 of FIG. 18) may be patterned with the second mask sub-region M_SBR2 (of FIG. 14) of the photomask M (of FIG. 14) to be formed.

According to example embodiments of the present inventive concept, a portion of the second shot region SR2 (e.g., the left half region of the second shot region SR2 of FIG. 18) may be patterned with the first mask sub-region M_SBR1 (of FIG. 14) of the photomask M (of FIG. 14) to be formed. A remaining portion of the second shot region SR2 (e.g., a right half region of the second shot region SR2 of FIG. 18) may be patterned with the second mask sub-region M_SBR2 (of FIG. 14) of the photomask M (of FIG. 14) to be formed.

According to example embodiments of the present inventive concept, the portion of the first shot region SR1 patterned with the second mask sub-region M_SBR2 (of FIG. 14) and the portion of the second shot region SR2 patterned with the first mask sub-region M_SBR1 (of FIG. 14) may be disposed to be adjacent to each other in the second direction D2. The first pattern PT1 (of FIG. 6) of the portion of the first shot region SR1 patterned with the second mask sub-region M_SBR2 (of FIG. 14) and the second pattern PT2 (of FIG. 6) of the portion of the second shot region SR2 patterned with the first mask sub-region M_SBR1 (of FIG. 14) may cross each other.

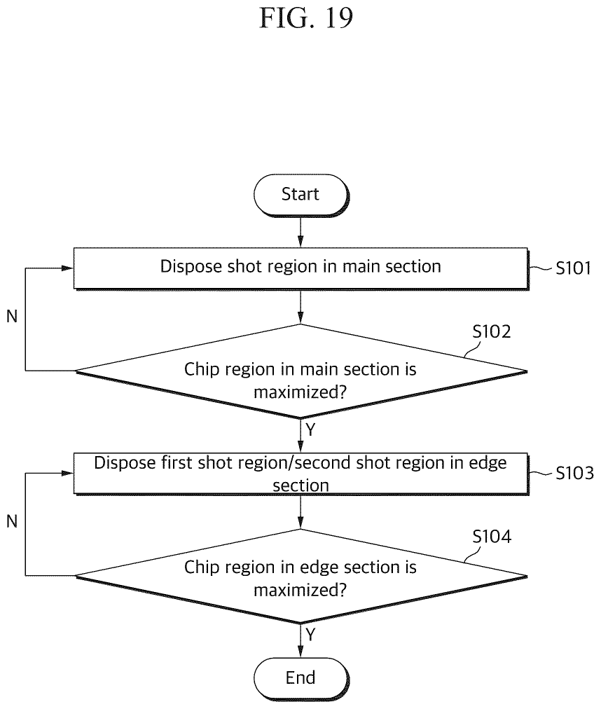

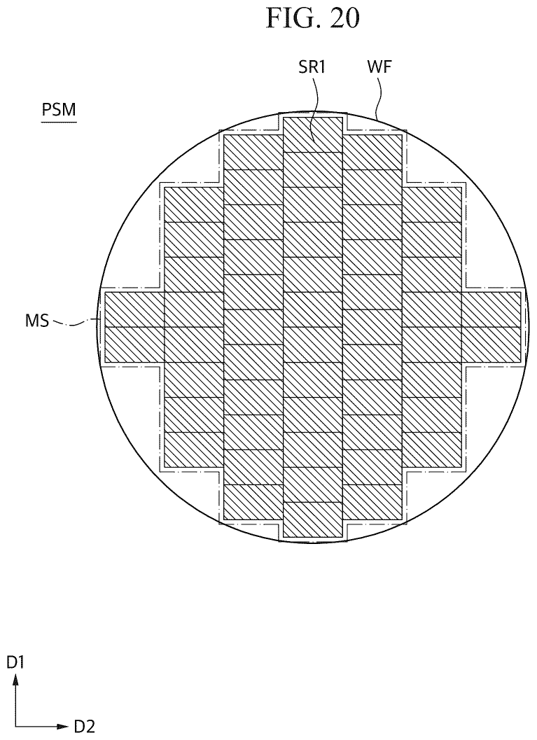

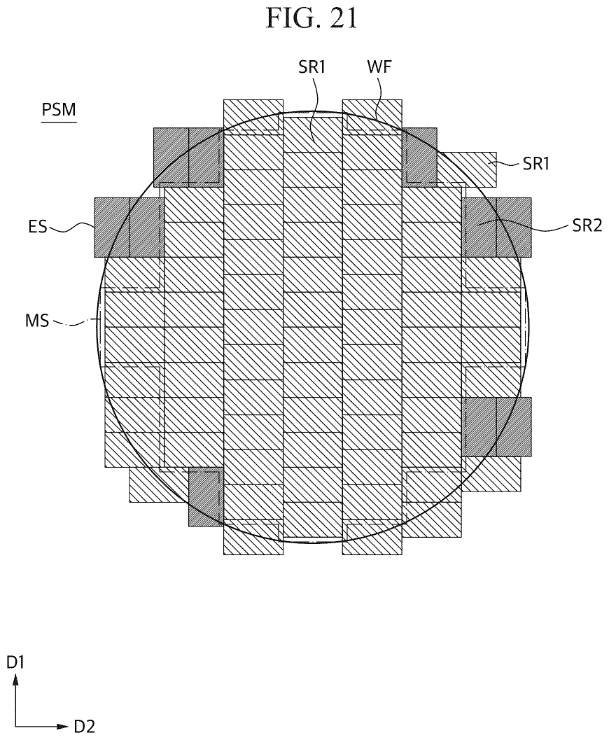

FIG. 19 is a flowchart for describing a method for forming a photo shot map of a semiconductor device according to example embodiments of the present inventive concept. FIG. 20 is a diagram for describing operations S101 and S102 of FIG. 19. FIG. 21 is a diagram for describing operations S103 and S104 of FIG. 19.

Referring to FIGS. 19 through 21, a method for fabricating a semiconductor device according to example embodiments of the present inventive concept may include forming a photo shot map PSM. The photo shot map PSM may include a disposition of shot regions of the substrate WF. For example, the photo shot map PSM may be associated with a disposition of the first shot region SR1 and the second shot region SR2 of the substrate WF. Forming the photo shot map PSM may be determination of the disposition of the shot regions in the substrate WF before exposure of the substrate WF to light by using the photomask M (of FIG. 2). Exposing the substrate WF to the light may be performed based on the formed photo shot map PSM.

For example, forming the photo shot map PSM may include determining the disposition of the first shot region SR1 and the second shot region SR2 in the substrate WF. Exposing the first shot region SR1 and the second shot region SR2 on the substrate WF to the light may be performed based on the disposition of the first shot region SR1 and the second shot region SR2 of the photo shot map PSM. The first shot region SR1 and the second shot region SR2 may be disposed in a relationship in which each is rotated by ninety degrees from another on an identical plane. For example, the first pattern PT1 (of FIG. 6) of the first shot region SR1 and the second pattern PT2 (of FIG. 6) of the second shot region SR2 may perpendicular to each other.

Referring to FIGS. 19 and 20, forming the photo shot map PSM may include disposing a shot region in the main section MS in operation S101. The shot region in the main section MS may have one type. As an example, the first shot region SR1 may be disposed in the main section MS. As another example, the second shot region SR2 may be disposed in the main section MS. FIG. 20 illustrates that the first shot region SR1 is disposed in the main section MS on the photo shot map PSM, but it is merely an example and not necessarily limited. The second shot region SR2 may be disposed in the main section MS on the photo shot map PSM.

Then, whether the number of chip regions CHP1 and CHP2 (of FIG. 5) in the main section MS is maximized may be determined in operation S102. When the number of chip regions CHP1 and CHP2 (of FIG. 5) in the main section MS is not maximized, which is calculated in operation S102, the shot region in the main section MS may be re-disposed by returning back to operation S101. When the number of chip regions CHP1 and CHP2 (of FIG. 5) in the main section MS, which is calculated in operation S102, is maximized, a disposition of shot regions in the main section MS may be determined.

Then, referring to FIGS. 19 and 21, forming the photo shot map PSM may include disposing the first shot region SR1 and the second shot region SR2 in the edge section ES in operation S103. The first shot region SR1 and the second shot region SR2 may be disposed together in the edge section ES1. An area of each of the first shot region SR1 and the second shot region SR2 in the edge section ES may not be entirely included in the substrate WF.

Then, whether the number of chip regions CHP1 and CHP2 (of FIG. 5) in the edge section ES is maximized may be determined in operation S104. When the number of chip regions CHP1 and CHP2 (of FIG. 5) in the edge section ES, which is calculated in operation S104, is not maximized, a shot region in the edge section ES may be re-disposed by returning back to operation S103. As an example, an arrangement of the first shot region SR1 and the second shot region SR2 which are disposed in the edge section ES may be changed. As another example, the number of each of the first shot region SR1 and the second shot region SR2 disposed in the edge section ES may be changed. When the number of chip regions CHP1 and CHP2 (of FIG. 5) in the edge section ES, which is calculated in operation S104, is maximized, a disposition of shot regions in the edge section ES may be determined, and a final photo shot map PSM may be formed.

According to example embodiments of the present inventive concept, the first shot region SR1 and the second shot region SR2 each may have a rectangular shape. Thus, the number of chip regions CHP1 and CHP2 formed to the substrate WF may vary depending on the disposition of the first shot region SR1 and the second shot region SR2. The number of chip regions CHP1 and CHP2 of the substrate WF may be maximized through disposing the first shot region SR1 and the second shot region SR2.

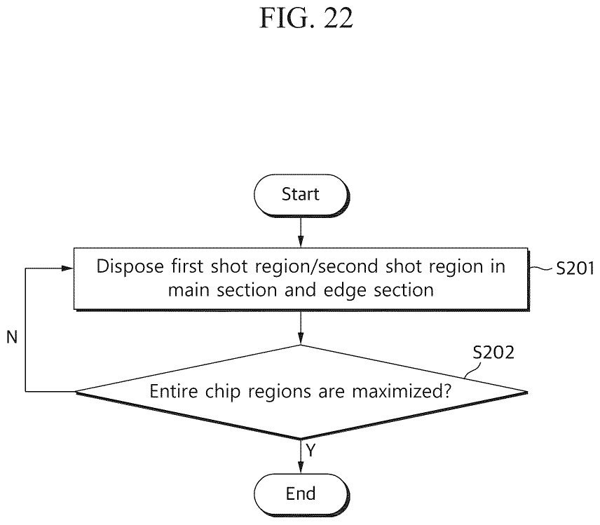

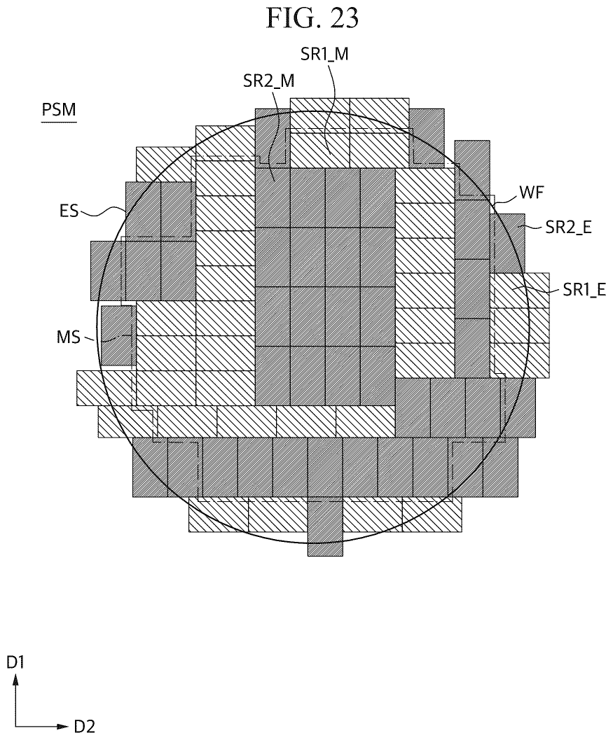

FIG. 22 is a flowchart for describing a method of forming a photo shot map of a semiconductor device according to example embodiments of the present inventive concept. FIG. 23 is a diagram for describing operations S201 and S202 of FIG. 22. In order to assist in understanding the present disclosure, a description will mainly focus on a point different from that described above with reference to FIGS. 19 through 21.

Referring to FIGS. 22 and 23, forming the photo shot map PSM may include disposing the first shot region SR1 and the second shot region SR2 in both of the main section MS and the edge section ES in operation S201. Both of the first shot region SR1 and the second shot region SR2 may be disposed in each of the main section MS and the edge section ES. The first shot region SR1 may include a first main shot region SR1_M and a first edge shot region SR1_E. The second shot region SR2 may include a second main shot region SR2_M and a second edge shot region SR2_E.

According to example embodiments of the present inventive concept, a disposition of the first edge shot region SR1_E and the second edge shot region SR2_E in the edge section ES may not be determined after a disposition of the first main shot region SR1_M and the second main shot region SR2_M in the main section MS is determined. The first main shot region SR1_M, the first edge shot region SR1_E, the second main shot region SR2_M, and the second edge shot region SR2_E may be disposed at the same time in the entire substrate WF which includes the main section MS and the edge section ES.

Then, whether the number of entire chip regions CHP1 and CHP2 (of FIG. 5) is maximized may be determined in operation S202. The number of entire chip regions CHP1 and CHP2 (of FIG. 5) may be the number of chip regions CHP1 and CHP2 (of FIG. 5) disposed in both of the main section MS and the edge section ES. When the number of entire chip regions CHP1 and CHP2 (of FIG. 5), which is calculated in operation S202, is not maximized, the first shot region SR1 and the second shot region SR2 may be re-disposed in the main section MS and the edge section ES by returning back to operation S201. When the number of entire chip regions CHP1 and CHP2 (of FIG. 5), which is calculated in operation S202, is maximized, a disposition of shot regions in the main section MS and the edge section ES may be determined, and a final photo shot map PSM may be formed.

FIGS. 22 and 23 illustrate that when the photo shot map PSM is formed, the first shot region SR1 and the second shot region SR2 are disposed at the same time in the main section MS and the edge section ES, but it is merely an example and not necessarily limited. For example, the disposition of the first edge shot region SR1_E and the second edge shot region SR2_E in the edge section ES may be determined after the disposition of the first main shot region SR1_M and the second main shot region SR2_M in the main section MS is determined. The first main shot region SR1_M and the second main shot region SR2_M may be disposed in the main section MS, and whether the number of chip regions CHP1 and CHP2 (of FIG. 5) in the main section MS is maximized is determined. Through this, the disposition of the first main shot region SR1_M and the second main shot region SR2_M in the main section MS may be determined. Then, the first edge shot region SR1_E and the second edge shot region SR2_E may be disposed in the edge section ES, and whether the number of chip regions CHP1 and CHP2 (of FIG. 5) in the edge section ES is maximized may be determined. Through this, the disposition of the first edge shot region SR1_E and the second edge shot region SR2_E in the edge section ES may be determined.

The various example embodiments of the present disclosure have been described above in detail, but the scope of the present disclosure is not limited thereto. It will be apparent to those skilled in the art that various changes and modifications may be allowed within a range of the technical spirit of the present disclosure. In addition, the above-described example embodiments may be implemented without a portion of elements thereof, and each of the example embodiments may be implemented in combination with another.

1. A method for fabricating a semiconductor device, the method comprising:
exposing a first pattern corresponding to a mask pattern to light in a first shot region of a substrate by using a photomask including the mask pattern, the first pattern extends in a first direction; and
exposing a second pattern corresponding to the mask pattern to the light in a second shot region disposed adjacent to the first shot region of the substrate by using the photomask, the second pattern extends in a second direction, wherein the first direction crosses the second direction.

2. The method of claim 1, wherein the first direction crosses the second direction at a right angle.

3. The method of claim 1, wherein each of the first shot region and the second shot region has a square shape.

4. The method of claim 1, further comprising exposing a first dummy pattern, which extends along the second direction, to the light in the first shot region,
wherein the first shot region includes:
a plurality of first chip regions; and
a first scribe region configured to divide the plurality of first chip regions,
wherein the first pattern is disposed in each of the plurality of first chip regions, and
wherein the first dummy pattern is disposed in the first scribe region.

5. The method of claim 4, further comprising exposing a second dummy pattern, which extends along the first direction, to the light in the second shot region,
wherein the second shot region includes:
a plurality of second chip regions; and
a second scribe region configured to divide the plurality of second chip regions,
wherein the second pattern is disposed in each of the plurality of second chip regions, and
wherein the second dummy pattern is disposed in the second scribe region.

6. The method of claim 5, wherein one edge of the first scribe region and one edge of the second scribe region are in contact with each other.

7. The method of claim 1, wherein the photomask includes:
a first edge configured to face another first edge; and
a second edge configured to face another second edge and cross the first edge,
wherein a direction in which a first shot edge of the first shot region, which corresponds to the first edge, is extended and a direction in which a third shot edge of the second shot region, which corresponds to the first edge, is extended cross each other.

8. The method of claim 7, wherein the direction in which the first shot edge is extended and the direction in which the third shot edge is extended cross the first direction and the second direction, respectively, at a non-perpendicular angle.

9. The method of claim 1, wherein a disposition direction of the photomask is fixed when the first pattern and the second pattern are exposed to the light, and
a disposition direction of the substrate relative to the photomask at a time of exposing the first pattern to the light and a disposition direction of the substrate relative to the photomask at a time of exposing the second pattern to the light cross each other.

10. A method for fabricating a semiconductor device, the method comprising:
exposing a first pattern corresponding to a mask pattern to light in a first shot region of a substrate by using a photomask including the mask pattern; and
exposing a second pattern corresponding to the mask pattern to the light in a second shot region adjacent to the first shot region of the substrate by using the photomask,
wherein the photomask includes:
a first edge configured to face another first edge; and
a second edge configured to face another second edge and cross the first edge,
wherein a direction in which a first shot edge of the first shot region, which corresponds to the first edge, is extended and a direction in which a third shot edge of the second shot region, which corresponds to the first edge, is extended cross each other.

11. The method of claim 10, wherein a disposition direction of the substrate relative to the photomask at a time of exposing the first pattern to the light and a disposition direction of the substrate relative to the photomask at a time of exposing the second pattern to the light cross each other.

12. The method of claim 10, wherein the substrate includes a plurality of shot regions corresponding to the photomask,
wherein the substrate further includes:
a main section in which an entire area of each of the plurality of shot regions is formed; and
an edge section that is configured to surround the main section and in which at least a portion of an area in an entire area of one of the plurality of shot regions is formed,
wherein the first shot region and the second shot region are disposed in the main section.

13. The method of claim 10, further comprising exposing a first dummy pattern to the light in the first shot region,
wherein the first shot region includes:
a plurality of first chip regions; and
a first scribe region configured to divide the plurality of first chip regions,
wherein the first pattern is formed in each of the plurality of first chip regions, and
wherein the first dummy pattern is formed in the first scribe region and extended along a direction, which crosses an extension direction of the first pattern.

14. The method of claim 10, wherein the first shot region and the second shot region are alternately disposed along a first direction and a second direction, which perpendicularly crosses the first direction.

15. The method of claim 10, wherein the substrate includes:
a first array in which a plurality of first shot regions including the first shot region is disposed along a first direction; and
a second array in which a plurality of second shot regions including the second shot region is disposed along the first direction,
wherein the first array and the second array are alternately disposed along a second direction crossing the first direction.

16. The method of claim 10, wherein the substrate includes:
a first array in which a plurality of first shot regions including the first shot region is disposed along a first direction; and
a second array in which a plurality of second shot regions including the second shot region is disposed along the first direction,
wherein a plurality of first arrays including the first array is disposed to be adjacent to each other along a second direction, which crosses the first direction.

17. The method of claim 10, wherein a length of the first edge and a length of the second edge are different.

18. The method of claim 10, wherein a direction in which the first pattern is extended and a direction in which the second pattern is intersect at a right angle.

19. The method of claim 10, further comprising:
measuring an overlay of the first pattern in the first shot region; and
measuring an overlay of the second pattern in the second shot region.

20. A method for fabricating a semiconductor device, the method comprising:
exposing a first pattern corresponding to a mask pattern to light in a first shot region of a substrate by using a photomask including the mask pattern, the first pattern extends in a first direction;
rotating the substrate by ninety degrees on a plane facing the photomask; and
exposing a second pattern corresponding to the mask pattern to the light in a second shot region disposed adjacent to the first shot region of the substrate by using the photomask, the second pattern extends in a second direction, wherein the first direction crosses the second direction.

21-24. (canceled)
